(19) United States
(12) Patent Application Publication
(10) Pub. No.: US 2026/0190778 A1
(43) Pub. Date: Jul. 2, 2026

(54) DISPLAY DEVICE

(71) Applicant: LG Display Co., Ltd., Seoul (KR)

(72) Inventors: Kyuhan YOON, Daegu (KR); Dayeong LEE, Gumi-si (KR)

(73) Assignee: LG Display Co., Ltd., Seoul (KR)

(21) Appl. No.: 19/358,174

(22) Filed: Oct. 14, 2025

(30) Foreign Application Priority Data
Dec. 23, 2024 (KR) 10-2024-0194629

(51) Int. Cl. H10K 59/80; H10K 59/40; H10K 102/00

(52) U.S. Cl. CPC H10K 59/873; H10K 59/40; H10K 59/879; H10K 59/8792; H10K 2102/351

(57) ABSTRACT

A display device can include a display area having a plurality of sub-pixels, a non-display area disposed outside of the display area and including a bezel area, a plurality of dams disposed in the bezel area, an encapsulation portion disposed on the plurality of dams, a touch member disposed on the encapsulation portion and including a touch sensor, a touch insulating layer and a passivation layer, a lens disposed on the touch member, and a protective layer disposed on the lens. The passivation layer covers the touch insulating layer extending to the bezel area.

### CROSS-REFERENCE TO RELATED APPLICATION

The present application claims priority to Korean Patent Application No. 10-2024-0194629, filed in the Republic of Korea on December 23, 2024, the entire contents of which is hereby expressly incorporated by reference into the present application.

### BACKGROUND

### Field

The present disclosure relates to a display device.

### Discussion of the Related Art

A display device is applied to various electronic devices. To this end, various display devices having characteristics of thinness, light weightness, and low power consumption have been developed.

For example, the display device can include a liquid crystal display (LCD) device, a field emission display (FED) display, an organic light-emitting display (OLED) device, and the like.

In addition to displaying an image on a screen, the display device can include a function of providing information to a user and allowing the user to make an input. A video or the image displayed on the screen of such a display device can be set not to be recognized by other people around the user depending on a type thereof. For example, the display device can be used as a means for displaying information of a vehicle. In addition, a display device applied to an electronic product such as a smartphone, a laptop computer, a tablet, or the like can be used in a public place.

### SUMMARY OF THE DISCLOSURE

To provide information displayed on a display device only to a user, a viewing angle adjusting member can be included in the display device. However, the display device including the viewing angle adjusting member can be vulnerable to external impact or moisture penetration. For example, when an organic insulating material of a bezel area or a pad area disposed outward (e.g., outside) of a display area is exposed, moisture can penetrate toward the display area through the organic insulating material. When moisture penetrates, a metal wiring such as a touch wiring can be electrolytically corroded or corroded.

In particular, when the touch wiring is damaged in the display device that enables a user input, a defect can occur during a touch operation.

Accordingly, the inventors of the present disclosure have invented an improved display device capable of preventing or minimizing moisture from penetrating into a metal wiring through an organic insulating material via various experiments.

In addition, a purpose of one or more embodiments of the present disclosure is to provide a display device capable of preventing or minimizing a touch wiring from being damaged by moisture penetration.

In addition, a purpose of an embodiment of the present disclosure is to provide a display device capable of preventing moisture from penetrating through an organic insulating material in a narrow bezel area and damaging a touch wiring.

Purposes according to the present disclosure are not limited to the above-mentioned purposes. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display device according to an embodiment of the present disclosure includes a display area including a plurality of sub-pixels, a non-display area disposed outward (e.g., outside) of the display area and including a bezel area, a plurality of dams disposed in the bezel area, an encapsulation portion disposed on the plurality of dams, a touch member disposed on the encapsulation portion and including a touch sensor, a touch insulating layer, and a passivation layer, a lens disposed on the touch member, and a protective layer disposed on the lens, and the passivation layer covers the touch insulating layer extending to the bezel area.

According to the embodiments of the present disclosure, the portion where the touch insulating layer made of the organic insulating material is exposed in the bezel area can be covered by the passivation layer made of the inorganic insulating material, thereby implementing a structure robust to the moisture permeation.

According to the embodiments of the present disclosure, as the organic insulating material is prevented from becoming the moisture penetration path, the metal wiring of the touch sensor can be prevented from being exposed to moisture, thereby preventing the metal wiring from being damaged by the corrosion or the like. Thus, the occurrence of the touch operation defect can be prevented or minimized, thereby improving the product reliability.

According to the embodiments of the present disclosure, the viewing angle adjusting member can be included, thereby preventing or minimizing the video or the image displayed on the screen of the display device from being shared with people other than the user.

In addition, according to the embodiments of the present disclosure, as the barrier structure disposed in the bezel area can be implemented in the same process as the viewing angle adjusting member, the process steps can be reduced. Accordingly, the production energy required for the production of the display device can be reduced and the greenhouse gas emission can be reduced.

The effects of the present disclosure are not limited to the above-mentioned effects, and other effects not mentioned can be clearly understood by those skilled in the art from the following descriptions.

In addition to the above-described effects, the specific effects of the present disclosure will be described together while describing specific matters for implementing the embodiments of the present disclosure below.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display panel according to embodiments of the present disclosure.

FIG. 2 is an enlarged view of an area I in FIG. 1 according to embodiments of the present disclosure.

FIG. 3 is a cross-sectional view taken along a line II-II' in FIG. 2 according to embodiments of the present disclosure.

FIG. 4 is a cross-sectional view taken along a line III-III' in FIG. 1 according to embodiments of the present disclosure.

FIG. 5 is a cross-sectional view taken along a line IV-IV' in FIG. 1 according to embodiments of the present disclosure.

FIG. 6 is a diagram illustrating an example in which a display device according to one or more embodiments of the present disclosure is applied.

### DETAILED DESCRIPTION OF THE EMBODIMENTS

Advantages and Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes "a" and "an" are intended to include the plural constitutes as well, unless the context clearly indicates otherwise. It will be further understood that the terms "comprise", "comprising", "include", and "including" when used in this disclosure, specify the presence of the stated features, integers, operations, elements, and/or components, but do not preclude the presence or addition of one or more other features, integers, operations, elements, components, and/or portions thereof. As used herein, the term "and/or" includes any and all combinations of one or more of associated listed items. Expression such as "at least one of" when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present "on" a second element or layer, the first element can be disposed directly on the second element or can be disposed indirectly on the second element with a third element or layer being disposed between the first and second elements or layers. It will be understood that when an element or layer is referred to as being "connected to", or "coupled to" another element or layer, it can be directly connected to, or coupled to the other element or layer, or one or more intervening elements or layers can be present therebetween. In addition, it will also be understood that when an element or layer is referred to as being "between" two elements or layers, it can be the only element or layer between the two elements or layers, or one or more intervening elements or layers can also be present.

Further, as used herein, when a layer, film, area, plate, or the like is disposed "on" or "on top" of another layer, film, area, plate, or the like, the former can directly contact the latter or still another layer, film, area, plate, or the like can be disposed between the former and the latter. As used herein, when a layer, film, area, plate, or the like is directly disposed "on" or "on top" of another layer, film, area, plate, or the like, the former directly contacts the latter and still another layer, film, area, plate, or the like is not disposed between the former and the latter. Further, as used herein, when a layer, film, area, plate, or the like is disposed "beneath" or “under” another layer, film, area, plate, or the like, the former can directly contact the latter or still another layer, film, area, plate, or the like can be disposed between the former and the latter. As used herein, when a layer, film, area, plate, or the like is directly disposed "beneath" or "under" another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms such as "first", "second", "third", and so on can be used herein to describe various elements, components, areas, layers and/or periods, these elements, components, areas, layers and/or periods should not be limited by these terms. These terms are used to distinguish one element, component, area, layer or section from another element, component, area, layer or period, and may not define order or sequence. Thus, a first element, component, area, layer or section as described under could be termed a second element, component, area, layer or period, without departing from the spirit and scope of the present disclosure.

When an embodiment can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term 'or' means 'inclusive or' rather than 'exclusive or'. For example, unless otherwise stated or clear from the context, the expression that 'x uses a or b' means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term can be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this can include a case where the signal is transferred from the node A to the node B via another node unless a phrase 'immediately transferred' or 'directly transferred' is used.

Throughout the present disclosure, "A and/or B" means A, B, or A and B, unless otherwise specified, and "C to D" means C inclusive to D inclusive unless otherwise specified.

In addition, “at least one” should be understood to include any combination of one or more of listed components. For example, at least one of first, second, and third components means not only a first, second, or third component, but also all combinations of two or more of the first, second, and third components. Further, the term “can” fully encompasses all the meanings and coverages of the term “may” and vice versa.

Hereinafter, embodiments of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure can work functionally.

Hereinafter, a display device according to embodiments of the present disclosure will be described with reference to the drawings. All the components of each display device/apparatus according to all embodiments of the present disclosure are operatively coupled and configured.

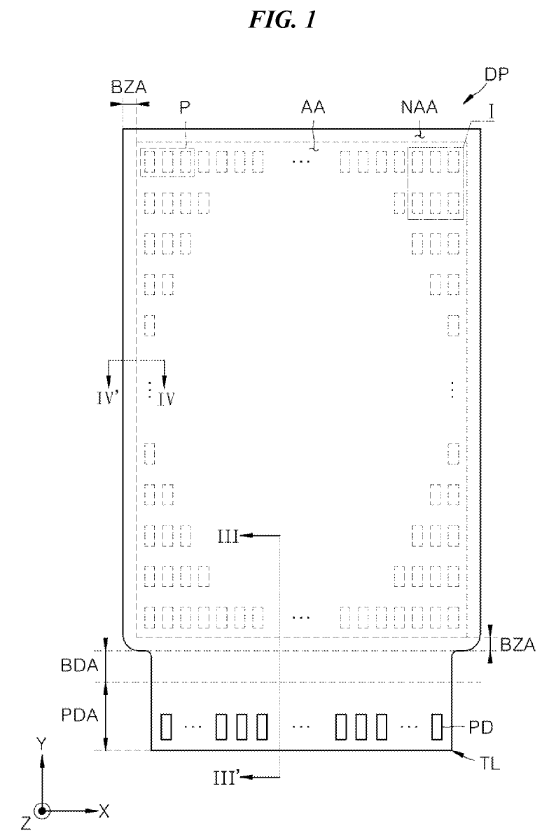

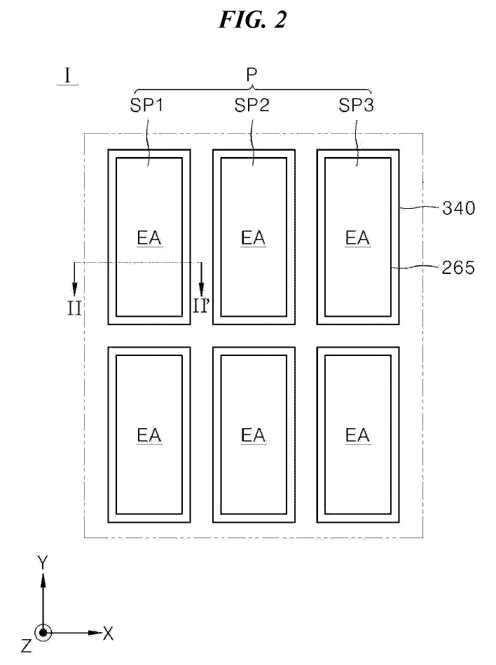

FIG. 1 is a plan view of a display panel according to an embodiment of the present disclosure. FIG. 2 is an enlarged view of an area I in FIG. 1.

Referring to FIGS. 1 and 2, the display device according to an embodiment of the present disclosure can include a display panel DP, a flexible printed circuit board, a timing controller, a data driver, a power driver, and the like.

The display panel DP can include a display area (or active area) AA and a non-display area (or non-active area) NAA. The display area AA can be an area in which an image is displayed. The non-display area NAA can be an area in which no image is displayed. The non-display area NAA can be located in a peripheral area (or an edge area) of the display panel DP, but may not be limited thereto. For example, an area other than a light emissive area in which light is emitted to the outside on the display panel DP can be referred to as the non-display area NAA. A bezel area BZA of the display device can be defined by the non-display area NAA. The bezel area BZA can surround an outer side of the display area AA.

A plurality of pixels P can be disposed in the display area AA. Each of the plurality of pixels P can be composed of a plurality of sub-pixels SP1, SP2, and SP3. The image can be displayed in the display area AA via the plurality of sub-pixels SP1, SP2, and SP3. The plurality of sub-pixels SP1, SP2, and SP3 can be arranged in an array on the display area AA. In an example, the plurality of sub-pixels SP1, SP2, and SP3 can be arranged in a matrix array by being spaced apart from each other in a first direction and a second direction intersecting the first direction of the display area AA. The first direction can be a horizontal direction, an X-axis direction, or a row direction, and the second direction can be a vertical direction, a Y-axis direction, or a column direction. However, the present disclosure may not be limited thereto, and an arrangement shape, an arrangement order, and an arrangement direction of the sub-pixels SP1, SP2, and SP3 can be variously changed.

In the present document, one pixel P being constructed by a first sub-pixel SP1, a second sub-pixel SP2, and a third sub-pixel SP3 is described as an embodiment, but the present disclosure is not limited thereto. For example, one pixel P can further include additional sub-pixels.

The sub-pixels SP1, SP2, and SP3 can be implemented to emit light of the same color, such as white light, or can be implemented to emit light of different colors, such as red, green, or blue light. For example, the first sub-pixel SP1 can render red, the second sub-pixel SP2 can render green, and the third sub-pixel SP3 can render blue.

Various wirings, circuits, and the like for driving the plurality of sub-pixels SP1, SP2, and SP3 of the display area AA can be disposed in the non-display area NAA. For example, driving circuits including a gate driving circuit and a data driving circuit can be disposed in the non-display area NAA. Several drivers for driving the display area AA can be disposed in the non-display area NAA. For example, the driver can include a gate driver and a data driver, but the present disclosure may not be limited thereto.

The non-display area NAA can include a pad area PDA in which a plurality of pads electrically connected to a printed circuit board or a driving circuit chip are disposed.

A bendable area BDA of the display panel DP can be bent to allow the printed circuit board and the driving circuit chip to be disposed on a rear surface of the display area AA of the display panel DP. The bendable area BDA can be an area located between the display panel DP and the pad area.

Referring to FIG. 2, on each of the sub-pixels SP1, SP2, and SP3, a bank 265 that divides a boundary area between neighboring sub-pixels and a light emissive area EA can be disposed. An area not covered by the bank 265 in each of the sub-pixels SP1, SP2, and SP3 can be the light emissive area EA. A lens 340, which is a viewing angle adjusting member, can be disposed to overlap each of the sub-pixels SP1, SP2, and SP3. The lens 340 can include a hemispherical lens, but may not be limited thereto. For example, the lens 340 can include a cylindrical lens. In an example, the lens 340 can function to prevent a video or the image displayed on a screen of the display device from being shared with people other than a user.

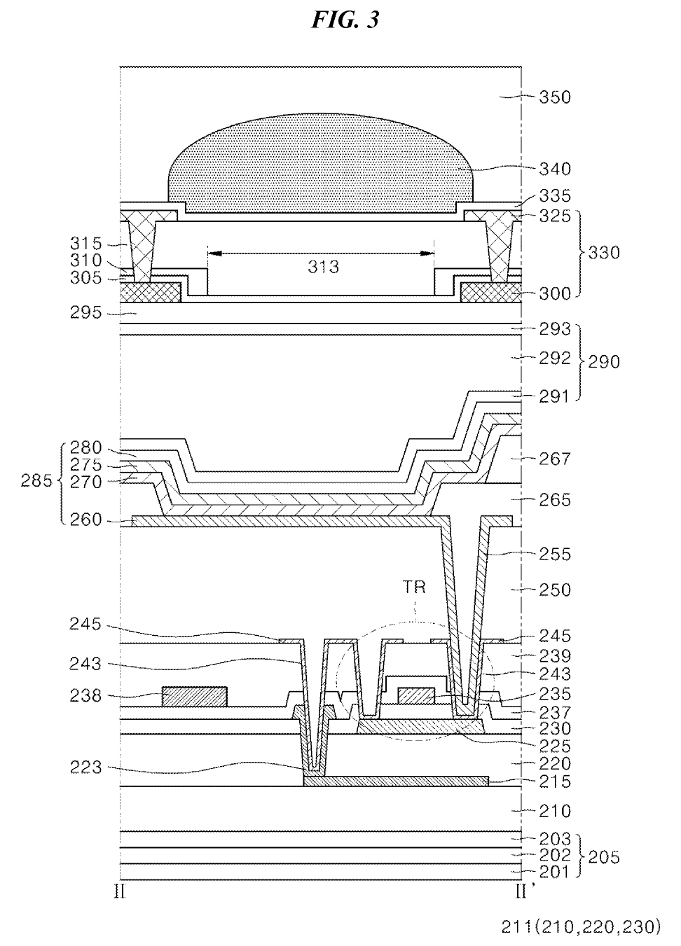

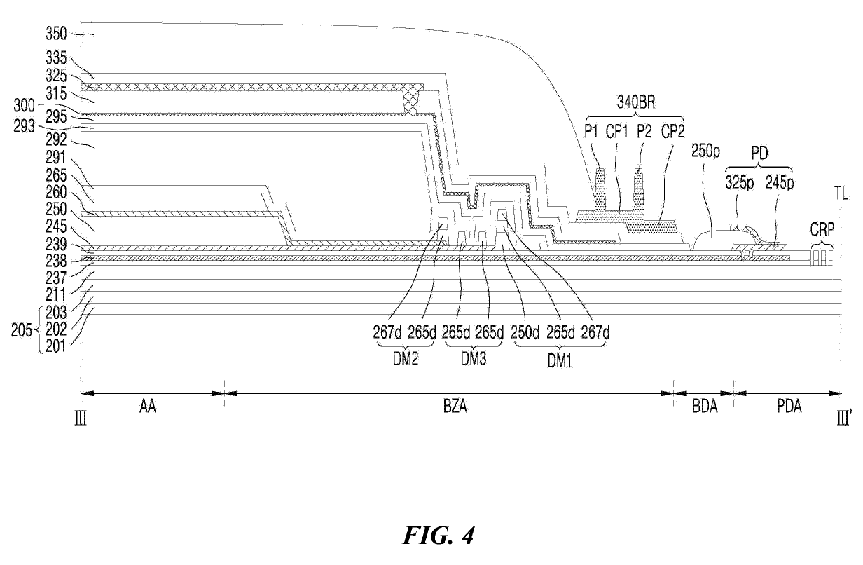

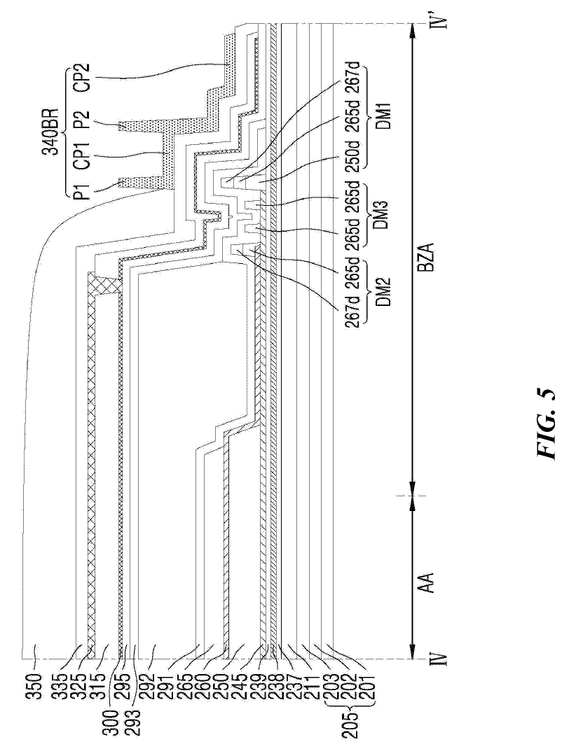

FIG. 3 is a cross-sectional view taken along a line II-II' in FIG. 2. FIG. 4 is a cross-sectional view taken along a line III-III' in FIG. 1. FIG. 5 is a cross-sectional view taken along a line IV-IV' in FIG. 1. FIG. 3 schematically illustrates one sub-pixel of the display device. In the present document, for convenience of description, it is described that one sub-pixel is constructed, but the present disclosure is not limited thereto.

Referring to FIGS. 3 to 5, the display panel DP (see FIG. 1) can include a pixel driving circuit including a transistor TR disposed on a substrate 205, a light-emitting element 285, the lens 340, and a protective layer 350.

One sub-pixel can include the light-emitting element 285 and the pixel driving circuit that applies a driving current to the light-emitting element 285. The pixel driving circuit is disposed on the substrate 205, and the light-emitting element 285 is disposed on the pixel driving circuit. The pixel driving circuit can include a driving transistor, one or more switching transistors, and a capacitor. In an example, the transistor TR can be the driving transistor, but may not be limited thereto.

The substrate 205 can be a flexible plastic substrate. When the substrate 205 is a plastic film, it can include multiple layers of insulating materials. For example, the substrate 205 can include a first base layer 201, a second base layer 203, and a support layer 202. The first base layer 201 and the second base layer 203 can be disposed to be spaced apart from each other in a vertical direction, and the support layer 202 can be disposed therebetween.

The first base layer 201 and the second base layer 203 can include an insulating material having ductility. For example, the first base layer 201 and the second base layer 203 can include polyimide. The support layer 202 can support the first and second base layers 201 and 203. The support layer 202 can include an insulating material that is relatively more rigid than that of the first and second base layers 201 and 203.

A first buffer layer 210 can be disposed on the substrate 205. The first buffer layer 210 can cover a surface of the substrate 205. For example, the first buffer layer 210 can entirely cover the surface of the substrate 205. The first buffer layer 210 can reduce or prevent penetration of moisture, oxygen, or impurities through the substrate 205. The first buffer layer 210 can be composed of a single layer or a multiple layers made of an inorganic insulating material such as silicon oxide (SiOx) or silicon nitride (SiNx).

A light shielding layer 215 can be disposed on the first buffer layer 210. The light shielding layer 215 can block external light incident on the transistor TR. To this end, the light shielding layer 215 can include an opaque metal material. A second buffer layer 220 can be disposed on the light shielding layer 215. The second buffer layer 220 can be disposed on a front surface of the substrate 205. The second buffer layer 220 can protect the transistor TR from moisture, oxygen, or impurities. The second buffer layer 220 can be composed of a single layer or a multiple layers made of an inorganic insulating material such as silicon oxide (SiOx) or silicon nitride (SiNx), but may not be limited thereto.

The transistor TR can be disposed on the second buffer layer 220. The transistor TR can include a semiconductor layer 225, a gate electrode 235, and source/drain electrodes 245. The semiconductor layer 225 can include a channel area and source/drain areas. An area of the semiconductor layer 225 overlapping the gate electrode 235 in the vertical direction can be the channel area. The source/drain areas can be disposed on both sides of the channel area, respectively. The semiconductor layer 225 can be composed of one of an oxide semiconductor layer, a polysilicon semiconductor layer, and a low-temperature polysilicon semiconductor layer, or a combination thereof. The semiconductor layer 225 can be disposed to overlap the light shielding layer 215 in the vertical direction. The light shielding layer 215 can block external light incident on the semiconductor layer 225.

A gate insulating layer 230 can be disposed between the semiconductor layer 225 and the gate electrode 235. The gate insulating layer 230 can cover the semiconductor layer 225. The gate insulating layer 230 can be composed of a single layer or a plurality of layers made of silicon oxide (SiOx) or silicon nitride (SiNx).

The gate electrode 235 can be disposed on the gate insulating layer 230. The gate electrode 235 can be composed of a single layer or a multiple layers made of one of molybdenum (Mo), aluminum (Al), chromium (Cr), gold (Au), titanium (Ti), nickel (Ni), neodymium (Nd), and copper (Cu) or an alloy thereof. However, the material is not limited thereto.

A via hole extending through the gate insulating layer 230 and the second buffer layer 220 can be disposed. The via hole can expose a portion of a surface of the light shielding layer 215. A via electrode 223 can be disposed on the via hole. The via electrode 223 can be connected to the light shielding layer 215 exposed by the via hole. The via electrode 223 can extend from inside of the via hole to a portion of a top surface of the gate insulating layer 230.

A first interlayer insulating layer 237 can be disposed on the gate electrode 235. The first interlayer insulating layer 237 can be composed of a single layer or multiple layers made of an inorganic insulating material such as silicon oxide (SiOx) or silicon nitride (SiNx).

An intermediate electrode 238 can be disposed on the first interlayer insulating layer 237. The intermediate electrode 238 can be disposed at a location different from an area in which the transistor TR is disposed. The intermediate electrode 238 can include a metal material. For example, the intermediate electrode 238 can be composed of a single layer or multiple layers made of one of molybdenum (Mo), aluminum (Al), chromium (Cr), gold (Au), titanium (Ti), nickel (Ni), neodymium (Nd), and copper (Cu), or an alloy thereof, but may not be limited thereto. In an example, the intermediate electrode 238 can include multiple wirings that transmit various signals provided to the display area AA from the driving circuit chip or the driver disposed on the printed circuit board. For example, the various signals can include a high potential voltage, a low potential voltage, a scan signal, a data signal, a touch driving signal, or the like, but the embodiment of the present disclosure may not be limited thereto.

A second interlayer insulating layer 239 can be disposed on the intermediate electrode 238. The second interlayer insulating layer 239 can include a plurality of contact holes 243. The plurality of contact holes 243 can extend through the second interlayer insulating layer 239, the first interlayer insulating layer 237, and the gate insulating layer 230 to expose portions of surfaces of the source/drain areas of the semiconductor layer 225. A portion of the contact hole 243 can be disposed to overlap the via electrode 223 in the vertical direction. The second interlayer insulating layer 239 can be composed of a single layer or multiple layers made of an inorganic insulating material such as silicon oxide (SiOx) or silicon nitride (SiNx).

The source/drain electrodes 245 can be disposed on the second interlayer insulating layer 239. The source/drain electrodes 245 can extend through the second interlayer insulating layer 239, the first interlayer insulating layer 237, and the gate insulating layer 230 to be connected to the source/drain areas of the semiconductor layer 225, respectively. A portion of the source/drain electrode 245 can be connected to the via electrode 223 to be connected to the light shielding layer 215. The source/drain electrode 245 can be composed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but may not be limited thereto. In an example, the source/drain electrode 245 can be a stacked structure of titanium/aluminum/titanium (Ti/Al/Ti).

A planarization layer 250 can be disposed on the source/drain electrodes 245 and the second interlayer insulating layer 239. The planarization layer 250 can planarize a step resulted from the pixel driving circuit thereunder. The planarization layer 250 can be a multi-layered structure. The planarization layer 250 can include an organic insulating material such as polyimide or an acrylic resin.

As shown in FIG. 4, the planarization layer 250 can be disposed to extend from the display area AA to a partial area of the bezel area BZA.

The light-emitting element 285 can be formed on the planarization layer 250. The light-emitting element 285 can include a first electrode 260, a light-emitting layer 270, a second electrode 275, and a capping layer 280.

The light-emitting element 285 can be electrically connected to the pixel driving circuit via the first electrode 260. For example, the planarization layer 250 can include a pixel contact hole 255. The pixel contact hole 255 can extend through the planarization layer 250 and the second interlayer insulating layer 239 and expose a portion of a surface of the source/drain electrodes 245.

The first electrode 260 of the light-emitting element 285 can be electrically connected to the source/drain electrodes 245. The first electrode 260 can be disposed on the pixel contact hole 255 to be connected to the source/drain electrodes 245.

The first electrode 260 can include a transparent conductive film. The first electrode 260 can include indium tin oxide (ITO) or indium zinc oxide (IZO). Alternatively, the first electrode 260 can have a single or multi-layered structure including a reflective metal film made of one of silver (Ag), aluminum (Al), gold (Au), nickel (Ni), and chromium (Cr) or an alloy thereof. The first electrode 260 can also be referred to as an anode electrode or a pixel electrode. As shown in FIGS. 4 and 5, the first electrode 260 can be formed to extend from the display area AA to a partial area of the bezel area BZA.

A bank 265 can be disposed on the first electrode 260. The bank 265 can be disposed to cover an edge of the first electrode 260. A portion of the bank 265 can extend to the planarization layer 250. A top surface of the first electrode 260 exposed without being covered by the bank 265 can become the light emissive area. The bank 265 can be made of an organic insulating material. The bank 265 can include, for example, photosensitive polyimide, photoacryl, or benzocyclobutene (BCB).

A spacer 267 can be further disposed on the bank 265. The spacer 267 can be disposed to prevent the bank 265 and the first electrode 260 from being damaged during the process. The spacer 267 can be made of the same material as the bank 265. In this case, it can be formed simultaneously with the bank 265 via a single process, but the present disclosure may not be limited thereto. In another example, the spacer 267 can be made of a material different from that of the bank 265 via a separate process. The spacer 267 can include an organic insulating material. The spacer 267 can include photosensitive polyimide, photoacryl, or benzocyclobutene (BCB).

The light-emitting layer 270 can be disposed on the first electrode 260. The light-emitting layer 270 can include a hole transport layer HTL, an organic light-emitting layer EML, an electron transport layer ETL, a hole blocking layer HBL, a hole injecting layer HIL, an electron blocking layer EBL, and electron injection layer EIL.

The second electrode 275 can be disposed on the light-emitting layer 270. The second electrode 275 can be commonly connected to the light-emitting layer 270 formed in all pixels. Accordingly, the second electrode 275 can also be referred to as a cathode electrode or a common electrode. The second electrode 275 can include a transflective conductive material. For example, it can be made of a metal material such as magnesium (Mg), silver (Ag), or an alloy (Ag—Mg) of silver (Ag) and magnesium (Mg). In an example, the second electrode 275 can include a transparent conductive film made of indium-tin-oxide (ITO) or indium-zinc-oxide (IZO).

The capping layer 280 can be disposed on the second electrode 275. The capping layer 280 can correct optical characteristics by preventing light generated from the light-emitting layer 270 from being lost.

An encapsulation portion 290 can be disposed on the light-emitting element 285. The encapsulation portion 290 can protect the light-emitting element 285 from external oxygen or moisture. The encapsulation portion 290 can extend to the non-display area NAA outward (e.g., outside) of the display area AA while covering the display area AA. For example, the encapsulation portion 290 can extend to a partial area of the bezel area BZA.

The encapsulation portion 290 can include a multi-layered structure in which a first encapsulation layer 291, a second encapsulation layer 292, and a third encapsulation layer 293 are disposed. The second encapsulation layer 292 can be a component disposed between the first encapsulation layer 291 and the third encapsulation layer 293.

The first encapsulation layer 291 can be disposed on the capping layer 280. The second encapsulation layer 292 can be disposed on the first encapsulation layer 291. The second encapsulation layer 292 can have a sufficient thickness to cover the first encapsulation layer 291 and to have a flat surface. The second encapsulation layer 292 can prevent foreign substances from penetrating into the light-emitting element 285. The third encapsulation layer 293 can be disposed on the second encapsulation layer 292.

The first encapsulation layer 291 and the third encapsulation layer 293 can include inorganic insulating materials. For example, each of the first encapsulation layer 291 and the third encapsulation layer 293 can include at least one of silicon nitride (SiNx), silicon oxide (SiOx), and silicon oxynitride (SiON). The second encapsulation layer 292 can include an organic insulating material. For example, the second encapsulation layer 292 can include at least one of epoxy, polyimide, polyethylene, and acrylate.

A touch member can be disposed on the encapsulation portion 290. A plurality of lens assemblies 340 can be disposed on the touch member. The touch member can include a touch buffer layer 295, a touch sensor 330, a touch interlayer insulating layer 305, a light blocking layer 310, a touch insulating layer 315, and a passivation layer 335.

The touch buffer layer 295 can be disposed on the third encapsulation layer 293. The touch buffer layer 295 can include an inorganic insulating material. For example, the touch buffer layer 295 can include silicon nitride (SiNx). The touch buffer layer 295 can function to relieve stress between the encapsulation portion 290 and the touch sensor 330.

The touch sensor 330 can include a plurality of touch electrodes 325 and a plurality of bridge electrodes 300. The plurality of touch electrodes 325 and the plurality of bridge electrodes 300 can be disposed on different layers. For example, the plurality of bridge electrodes 300 can be disposed on the touch buffer layer 295. The plurality of touch electrodes 325 can be disposed on the touch insulating layer 315.

The plurality of touch electrodes 325 or the bridge electrodes 300 can include a single layer or multiple layers made of one of molybdenum (Mo), aluminum (Al), chromium (Cr), gold (Au), titanium (Ti), nickel (Ni), neodymium (Nd), and copper (Cu) or an alloy thereof. For example, the plurality of touch electrodes 325 or bridge electrodes 300 can be a stacked structure of titanium/aluminum/titanium (Ti/Al/Ti).

The touch interlayer insulating layer 305 can be disposed on the plurality of bridge electrodes 300 and the touch buffer layer 295. The touch insulating layer 315 can be disposed between the plurality of touch electrodes 325 and the plurality of bridge electrodes 300, for example, between an upper part of the touch electrode and the bridge electrode. The light blocking layer 310 can be disposed on the touch interlayer insulating layer 305. The plurality of touch electrodes 325 can be disposed on the touch insulating layer 315 to be spaced apart from each other. The bridge electrode 300 can electrically connect adjacent touch electrodes 325 to each other. To this end, each touch electrode 325 can pass through the touch insulating layer 315, the light blocking layer 310, and the touch interlayer insulating layer 305 to be electrically connected to the bridge electrode 300. The adjacent touch electrodes 325 can be insulated from each other by the passivation layer 335.

The touch interlayer insulating layer 305 or the passivation layer 335 can include an inorganic insulating material. For example, the touch interlayer insulating layer 305 or the passivation layer 335 can be made of an inorganic insulating material including silicon nitride (SiNx).

The touch insulating layer 315 can disperse or condense an optical path of light generated from the light-emitting element 285 and provide the same in a direction of the lens 340. To this end, the touch insulating layer 315 can be formed to have a sufficient thickness. It can be difficult to implement the inorganic insulating material with a thickness required by the touch insulating layer 315. Accordingly, the touch insulating layer 315 can include an organic insulating material. For example, the touch insulating layer 315 can include an organic insulating material such as an acryl resin, an epoxy resin, a phenolic resin, a polyamide resin, or a polyimide resin. However, the material is not limited thereto. The touch insulating layer 315 can extend from the display area AA to a partial area of the bezel area BZA.

The light blocking layer 310 can be disposed on the touch interlayer insulating layer 305. The light blocking layer 310 can prevent color mixing between adjacent light-emitting elements 285 from occurring, block light from the outside, or block light reflected from the outside. Accordingly, luminance of the display device can be further improved.

To this end, the light blocking layer 310 can include an opaque material. For example, the light blocking layer 310 can include an organic insulating material including a black pigment, a black dye, or the like. In an example, the organic insulating material can be an organic material such as a benzocyclobutene resin, an epoxy resin, a polyimide resin, an acrylic resin, or a photosensitive polymer, but may not be limited thereto.

The light blocking layer 310 can include multiple openings 313. In an example, the opening 313 can be disposed such that at least a partial area thereof overlaps a light emissive area of the light-emitting element 285. In an embodiment, one opening 313 can overlap the light emissive area of one sub-pixel, but the present disclosure may not be limited thereto.

The plurality of lens assemblies 340 can be disposed on the passivation layer 335. Adjacent lens assemblies 340 can be arranged to be spaced apart from each other by a predetermined spacing. In an example, one lens 340 can be disposed to overlap one opening 313 of the light blocking layer 310.

The protective layer 350 can be disposed on the lens 340. The protective layer 350 can have a sufficient thickness to cover the lens 340 and to have a flat surface on the substrate 205. In an example, a refractive index of the protective layer 350 can be smaller than a refractive index of the lens 340. Accordingly, light that has passed through the lens 340 can be prevented from being reflected toward the substrate 205.

The lens 340 can be a hemispherical lens overlapping the opening 313 in the vertical direction. For example, the lens 340 can have a hemispherical shape in which a convex surface protrudes toward the protective layer 350. An incident surface facing the protruding convex surface of the lens 340 and on which light generated from the light-emitting element 285 is incident can be a flat plane. The incident surface of the lens 340 can be in contact with the passivation layer 335.

Light generated from the light-emitting element 285 and passed through the opening 313 can be provided to the incident surface of the lens 340, refracted by the convex surface of the lens 340, and emitted to the outside. Light generated in various directions from the light-emitting element 285 can be condensed in a forward direction by changing optical paths thereof by the lens 340. Accordingly, a side surface viewing angle of the display device can be controlled. In the embodiment of the present disclosure, the lens 340, which is a viewing angle adjusting member, can be included to prevent the video or the image displayed on the screen of the display device from being shared with people other than the user.

The protective layer 350 can extend from the display area AA to a partial area of the bezel area BZA. The protective layer 350 can include an organic insulating material. For example, the protective layer 350 can include at least one of epoxy, polyimide, polyethylene, and acrylate. However, the material is not limited thereto.

Referring to FIGS. 4 and 5, in the display device according to the embodiment of the present disclosure, a plurality of dams DM1, DM2, and DM3 can be disposed in the bezel area BZA. The second encapsulation layer 292 can be disposed inward (e.g., inside) of the plurality of dams DM1, DM2, and DM3.The plurality of dams DM1, DM2, and DM3 can prevent the second encapsulation layer 292 including the organic insulating material from overflowing in an outward direction of the bezel area BZA. The plurality of dams DM1, DM2, and DM3 can include a first dam DM1, a second dam DM2, and a third dam DM3.

In an example, the plurality of dams DM1, DM2, and DM3 can be disposed to surround a portion outward (e.g., outside) of the display area AA in the display panel DP (see FIG. 1). For example, the plurality of dams DM1, DM2, and DM3 can be disposed to surround portions of an upper side, a left side, a right side, and a lower side of the display panel DP. Among the plurality of dams DM1, DM2, and DM3, the first dam DM1 can be located at the outermost side and can be disposed adjacent to the bendable area BDA. The second dam DM2 among the plurality of dams DM1, DM2, and DM3 can be disposed closest to the display area AA. The third dam DM3 can be disposed between the first dam DM1 and the second dam DM2.

The first dam DM1 can include a structure in which a first layer 250d, a second layer 265d, and a third layer 267d are disposed or stacked in an upward direction from the bottom. The second dam DM2 can include a structure in which the second layer 265d and the third layer 267d are disposed or stacked in the upward direction from the bottom. The third dam DM3 can include a structure of the second layer 265d. The first layer 250d can be made of the same material in the process of forming the planarization layer 250 in the display area AA. The second layer 265d can be made of the same material in the process of forming the bank 265 of the display area AA. In addition, the third layer 267d can be made of the same material in the process of forming a spacer 267 of the display area AA. However, embodiments of the present disclosure are not limited thereto.

The plurality of dams DM1, DM2, and DM3 can be covered with the first encapsulation layer 291 and the third encapsulation layer 293 extending from the display area AA. For example, it can be a structure in which respective one surfaces of the first encapsulation layer 291 and the third encapsulation layer 293 are in contact with each other and are stacked in the upward direction from the bottom on top of each of the plurality of dams DM1, DM2, and DM3. The material of the second encapsulation layer 292 can be prevented from overflowing in the outward direction of the bezel area BZA by the first dam DM1.

The touch buffer layer 295 can be disposed on the third encapsulation layer 293 of the bezel area BZA. The touch buffer layer 295 can extend from the display area AA to the bezel area BZA. The bridge electrode 300 can be disposed on the touch buffer layer 295. The bridge electrode 300 can extend from the display area AA to a partial area of the bezel area BZA. A partial area of the bridge electrode 300 extending to the bezel area BZA can be a first link wiring.

The touch insulating layer 315 can be disposed on the bridge electrode 300. The touch electrode 325 can be disposed on the touch insulating layer 315. The touch electrode 325 can extend from the display area AA to a partial area of the bezel area BZA. A partial area of the touch electrode 325 extending to the bezel area BZA can be a second link wiring. The touch electrode 325 can pass through the touch insulating layer 315 in the bezel area BZA to be electrically connected to the bridge electrode 300.

The touch insulating layer 315 can be disposed to extend from the display area AA to a partial area of the bezel area BZA. The touch insulating layer 315 disposed in the display area AA should be formed to have a sufficient thickness to provide a path of light generated from the light-emitting element 285 toward the lens 340. Accordingly, the touch insulating layer 315 can be made of an organic insulating material instead of an inorganic insulating material that is difficult to be implemented with the sufficient thickness. However, the organic insulating material can be vulnerable to external impact or moisture penetration. For example, when the touch insulating layer 315 including the organic insulating material is exposed to the outside in the bezel area BZA, an exposed portion of the organic insulating material can become a moisture permeation path through which moisture penetrates toward the display area AA.

A defect can occur in a metal wiring such as the touch electrode 325 or the bridge electrode 300 of the touch sensor 330 by moisture penetrated toward the display area AA. For example, when a voltage is applied in the state in which moisture is permeated into the touch sensor 330, the metal wiring can be electrolytically corroded or corroded by an electric field and moisture.

In particular, as the bezel area is reduced to secure an area size of the display area AA, moisture penetrating from the touch insulating layer 315 can more easily reach the metal wiring. Accordingly, because the electrolytic corrosion or the corrosion of the metal wiring is accelerated and the defect occurs during a touch operation, reliability of the display device can be reduced.

Accordingly, the touch insulating layer 315 extending to the bezel area BZA and exposed and the passivation layer 335 including the inorganic insulating material are in direct contact with each other, thereby preventing the touch insulating layer 315 from being exposed to the outside. For example, the passivation layer 335 can be disposed to extend from the display area AA to a partial area of the bezel area BZA. In an example, the passivation layer 335 can cover an exposed surface of the touch insulating layer 315 extending to the bezel area BZA. In an example, the passivation layer 335 can be disposed to cover at least a distal end of the touch insulating layer 315 in the bezel area BZA.

As such, the touch insulating layer 315 can be blocked from becoming the moisture penetration path. Accordingly, because the metal wiring of the touch sensor 330 can be prevented from being exposed to moisture, the metal wiring can be prevented from being damaged by the electrolytic corrosion or the corrosion, thereby preventing a touch operation failure from occurring. Accordingly, product reliability of the display device can be improved.

The bezel area BZA of the display device according to an embodiment of the present disclosure can include a barrier structure 340BR. The barrier structure 340BR can be disposed to surround the portion outward (e.g., outside) of the display area AA in the display panel DP (see FIG. 1). For example, the barrier structure 340BR can be disposed to surround upper, left, right, and lower portions of the display panel DP. In an example, the barrier structure 340BR can be disposed along the bezel area BZA.

The barrier structure 340BR can be disposed on the passivation layer 335 covering the touch insulating layer 315. For example, it can cover the exposed area of the passivation layer 335 in the bezel area BZA. Accordingly, the exposed area of the passivation layer 335 can be protected. In an example, the barrier structure 340BR can prevent the protective layer 350 from overflowing into the pad area PDA.

The barrier structure 340BR can include a first barrier pattern P1, a second barrier pattern P2, a first connection portion CP1, and a second connection portion CP2. The first connection portion CP1 can be located between the first barrier pattern P1 and the second barrier pattern P2, and the second connection portion CP2 can extend in a direction of the bendable area BDA. In an example, the first barrier pattern P1, the second barrier pattern P2, the first connection portion CP1, and the second connection portion CP2 can be integrally formed and continuously connected to each other.

The first barrier pattern P1 and the second barrier pattern P2 can have a thickness different from that of the first connection portion CP1 and the second connection portion CP2. For example, the first barrier pattern P1 and the second barrier pattern P2 can have a thickness greater than that of the first connection portion CP1 and the second connection portion CP2 to prevent the protective layer 350 from overflowing into the pad area PDA. In an example, the first barrier pattern P1 and the second barrier pattern P2 can have the same thickness, but the present disclosure may not be limited thereto. In an example, the second barrier pattern P2 disposed at a location closer to the bendable area BDA than the first barrier pattern P1 can be relatively thicker than the first barrier pattern P1 to prevent the protective layer 350 from overflowing into the pad area PDA.

The first barrier pattern P1, the second barrier pattern P2, the first connection portion CP1, and the second connection portion CP2 of the barrier structure 340BR can be implemented to have different thicknesses using a halftone mask.

The barrier structure 340BR can be made of the same material and formed in the same process as the lens 340, which is the viewing angle adjusting member, of the display area AA. Accordingly, because an increase in separate process steps for forming the barrier structure 340BR can be prevented, a total process steps can be reduced. Therefore, because production energy required for production of the display device can be reduced, emission of greenhouse gas can be reduced.

The barrier structure 340BR disposed in the bezel area BZA between the bendable area BDA, which is a lower side of the display panel DP, and the display area AA can be disposed outward (e.g., outside) of the plurality of dams DM1, DM2, and DM3. For example, the barrier structure 340BR can be disposed outward (e.g., outside) of the first dam DM1 disposed at the outermost side among the plurality of dams DM1, DM2, and DM3.

The bezel area BZA at the upper side, the left side, and the right side of the display panel DP can be relatively narrower than the bezel area BZA at the lower side of the display panel DP. Accordingly, the barrier structure 340BR disposed in the bezel area BZA at the upper side, the left side, and the right side of the display panel DP can be disposed to overlap at least one of the plurality of dams DM1, DM2, and DM3 in the vertical direction. For example, as illustrated in FIG. 5, the barrier structure 340BR can be disposed to overlap the first dam DM1 disposed at the outermost side among the plurality of dams DM1, DM2, and DM3. In an example, the first barrier pattern P1 of the barrier structure 340BR can overlap the first dam DM1 in the vertical direction, and the second barrier pattern P2, the first connection portion CP1, and the second connection portion CP2 can be disposed to extend in an edge direction of the bezel area BZA.

The non-display area NAA of the display device according to an embodiment of the present disclosure can include the bendable area BDA and the pad area PDA. A bending protective layer 250p can be disposed in the bendable area BDA. The pad area PDA can include a pad portion PD. The pad portion PD can include a first pattern 245p and a second pattern 325p. The first pattern 245p can be electrically connected to the intermediate electrode 238 extending from the display area AA through the second interlayer insulating layer 239 on the pad area PDA. In an example, the first pattern 245p can be made of the same material and formed in the same process as the source/drain electrodes 245. The second pattern 325p can be made of the same material and formed in the same process as the touch electrode 325.

The bending protective layer 250p can prevent the intermediate electrode 238 extending to the bendable area BDA from being damaged and disconnected during the bending operation. In an example, the bending protective layer 250p can be made of the same material and formed in the same process as the planarization layer 250, but the present disclosure may not be limited thereto. For example, the bending protective layer 250p can be made of a material different from that of the planarization layer 250 and can include a material capable of protecting the intermediate electrode 238 on the bendable area BDA.

The pad area PDA can include a crack prevention pattern CRP. The crack prevention pattern CRP can be disposed between the pad portion PD and a trimming line TL. The crack prevention pattern CRP can be disposed outward (e.g., outside) of the pad portion PD. The crack prevention pattern CRP can include a plurality of grooves extending through the first interlayer insulating layer 237 and the second interlayer insulating layer 239. The trimming line TL can be a reference line for cutting the substrate 205 via a trimming process based on a shape of an applied product. For example, the trimming process can be performed using a laser, but the present disclosure may not be limited thereto. The crack prevention pattern CRP can prevent a crack occurring on the substrate 205 from progressing in a direction of the display area AA during the trimming process and a subsequent process.

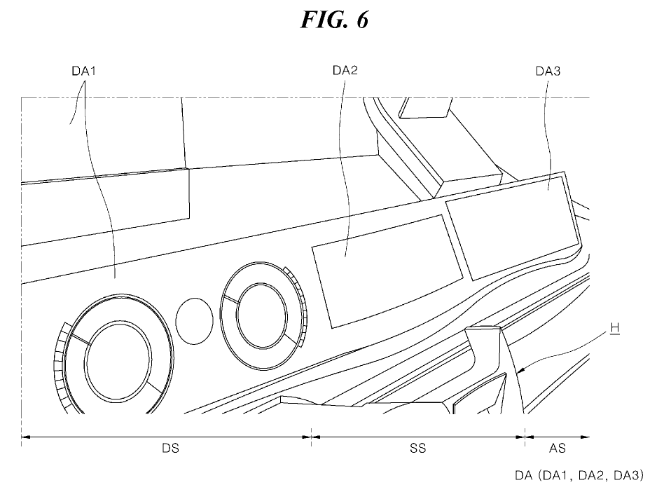

FIG. 6 illustrates an example in which a display device according to an embodiment of the present disclosure is applied.

Referring to FIG. 6, a display device including the display panel DP (see FIG. 1) according to an embodiment of the present disclosure can be disposed inside a vehicle. For example, the display device can be disposed on a front surface of a dashboard inside the vehicle, and the display panel DP can include a first display area DA1, a second display area DA2, and a third display area DA3. In an example, the first display area DA1 can be disposed forward of a steering wheel H of a driver's seat, the third display area DA3 can be disposed in front of a passenger seat, and the second display area DA2 can be disposed in a common space between the driver's seat and the passenger seat. The first display area DA1 can provide information of an instrument panel indicating a driving state to the user. The second display area DA2 or the third display area DA3 can display a navigation, a video, or the like based on a user's selection or the driving state of the vehicle. In an example, when the vehicle is traveling, the second display area DA2 or the third display area DA3 can control the side surface viewing angle so as not to interfere with driver's driving. Each of at least one of the first to third display areas DA1-DA3 can have the configuration of the display device/panel discussed above according to the embodiments of the present disclosure, e.g., the display device of FIGS. 1-5.

A display device according to various embodiments of the present disclosure can be described as follows.

A display device according to an embodiment of the present disclosure includes a display area including a plurality of sub-pixels, a non-display area disposed outward of the display area and including a bezel area, a plurality of dams disposed in the bezel area, an encapsulation portion disposed on the plurality of dams, a touch member disposed on the encapsulation portion and including a touch sensor, a touch insulating layer, and a passivation layer, a lens disposed on the touch member, and a protective layer disposed on the lens, wherein the passivation layer covers the touch insulating layer extending to the bezel area.

According to various embodiments of the present disclosure, the passivation layer can cover at least a distal end of the touch insulating layer.

According to various embodiments of the present disclosure, the display device can further include a barrier structure disposed on the passivation layer in the bezel area.

According to various embodiments of the present disclosure, the barrier structure can be disposed outward of the plurality of dams.

According to various embodiments of the present disclosure, one side of the barrier structure can be in contact with the protective layer.

According to various embodiments of the present disclosure, the barrier structure can include a first barrier pattern having one side in contact with the protective layer, a second barrier pattern disposed to be spaced apart from the first barrier pattern, a first connection portion disposed between the first barrier pattern and the second barrier pattern, and a second connection portion extending from the second barrier pattern.

According to various embodiments of the present disclosure, the first barrier pattern, the second barrier pattern, the first connection portion, and the second connection portion can be continuously connected to each other.

According to various embodiments of the present disclosure, a first thickness of the first barrier pattern and the second barrier pattern can be different from a second thickness of the first connection portion and the second connection portion.

According to various embodiments of the present disclosure, the first thickness of the first barrier pattern and the second barrier pattern can be greater than the second thickness of the first connection portion and the second connection portion.

According to various embodiments of the present disclosure, the barrier structure can be formed in the same process as the lens and include the same material as the lens.

According to various embodiments of the present disclosure, the bezel area can be located to surround an upper side, a lower side, a left side, and a right side of the display area, and the barrier structure can be disposed along the bezel area.

According to various embodiments of the present disclosure, the barrier structure disposed at an upper side, a left side, and a right side of the bezel area can be disposed to overlap at least one of the plurality of dams in a vertical direction.

According to various embodiments of the present disclosure, the touch insulating layer can include an organic insulating material, and the passivation layer can include an inorganic insulating material.

According to various embodiments of the present disclosure, the touch member can further include a touch buffer layer disposed between the encapsulation portion and the touch sensor, a touch interlayer insulating layer disposed between the touch buffer layer and the touch sensor, and a light blocking layer disposed on the touch interlayer insulating layer and including a plurality of openings.

According to various embodiments of the present disclosure, the lens can be disposed to overlap one of the openings of the light blocking layer in a vertical direction.

Although some embodiments of the present disclosure have been described above with reference to the accompanying drawings, the present disclosure may not be limited to some embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some embodiments as described above are not restrictive but illustrative in all respects.

What is claimed is:

1. A display device comprising:
a display area including a plurality of sub-pixels;
a non-display area disposed outside of the display area and including a bezel area;
a plurality of dams disposed in the bezel area;
an encapsulation portion disposed on the plurality of dams;
a touch member disposed on the encapsulation portion and including a touch sensor, a touch insulating layer, and a passivation layer;
a lens disposed on the touch member; and
a protective layer disposed on the lens,
wherein the passivation layer covers the touch insulating layer extending to the bezel area.

2. The display device of claim 1, wherein the passivation layer covers at least a distal end of the touch insulating layer.

3. The display device of claim 1, further comprising a barrier structure disposed on the passivation layer in the bezel area.

4. The display device of claim 3, wherein the barrier structure is disposed outside of the plurality of dams.

5. The display device of claim 3, wherein one side of the barrier structure is in contact with the protective layer.

6. The display device of claim 3, wherein the barrier structure includes:
a first barrier pattern having one side in contact with the protective layer;
a second barrier pattern disposed to be spaced apart from the first barrier pattern;
a first connection portion disposed between the first barrier pattern and the second barrier pattern; and
a second connection portion extending from the second barrier pattern.

7. The display device of claim 6, wherein the first barrier pattern, the second barrier pattern, the first connection portion, and the second connection portion are continuously connected to each other.

8. The display device of claim 7, wherein a first thickness of the first barrier pattern and the second barrier pattern is different from a second thickness of the first connection portion and the second connection portion.

9. The display device of claim 8, wherein the first thickness of the first barrier pattern and the second barrier pattern is greater than the second thickness of the first connection portion and the second connection portion.

10. The display device of claim 3, wherein the barrier structure is formed in a same process as the lens and includes a same material as the lens.

11. The display device of claim 3, wherein the bezel area is located to surround an upper side, a lower side, a left side, and a right side of the display area, and
wherein the barrier structure is disposed along the bezel area.

12. The display device of claim 11, wherein the barrier structure disposed at an upper side, a left side, and a right side of the bezel area is disposed to overlap at least one of the plurality of dams in a vertical direction.

13. The display device of claim 11, wherein the barrier structure disposed at a lower side of the bezel area is disposed outside of the plurality of dams.

14. The display device of claim 1, wherein the touch insulating layer includes an organic insulating material, and the passivation layer includes an inorganic insulating material.

15. The display device of claim 1, wherein the touch member further includes:
a touch buffer layer disposed between the encapsulation portion and the touch sensor;
a touch interlayer insulating layer disposed between the touch buffer layer and the touch sensor; and
a light blocking layer disposed on the touch interlayer insulating layer and including a plurality of openings.

16. The display device of claim 15, wherein the lens is disposed to overlap one of the plurality of openings of the light blocking layer in a vertical direction.

17. The display device of claim 1, wherein the encapsulation portion includes a plurality of encapsulation layers, and
wherein at least one of the plurality of encapsulation layers includes an organic insulating material and is disposed inward of the plurality of dams.

18. The display device of claim 17, wherein at least one of the plurality of dams includes a structure stacked in an upward direction from a bottom of the structure.

19. A vehicle comprising:
at least one interior display area including the display device of claim 1.
